(19) United States
(12) Patent Application Publication
(10) Pub. No.: US 2004/0169438 A1
(43) Pub. Date: Sep. 2, 2004

(54) Additional contact for an electric component and piezoelectric component in the form of a multilayer structure

(76) Inventors: Dieter Cramer, Munchen (DE); Iris Hahn, Neubiberg (DE); Carsten Schuh, Baldham (DE); Thorsten Steinkopff, Eglharting (DE); Andreas Wolff, Munchen (DE)

Correspondence Address: YOUNG & THOMPSON, 745 SOUTH 23RD STREET 2ND FLOOR, ARLINGTON, VA, 22202

(21) Appl. No.: 10/482,206

(22) PCT Filed: Apr. 29, 2002
(86) PCT No.: PCT/EP02/04723

(30) Foreign Application Priority Data
Jun. 29, 2001 (DE) 101-31-621.6

(51) Int. Cl. H01L 41/083

(52) U.S. Cl. 310/328

(57) ABSTRACT

The invention relates, inter alia, to an additional contact (30) for a piezoelectric component (10) in the form of a multilayer structure and to a corresponding component, wherein the piezoelectric component (10) is formed by a stack (17) of alternating piezoelectric ceramic layers and electrode layers. The additional contact (30) has a contact element (31) with a contact zone (33) for connection to an electrical connecting element (20) and with a fastening zone (34) for connection to a metallized part (15, 16). In order to minimize harmful tensile/pressure loads in the additional contact (30), the additional contact (30), especially the contact element (31), is shaped so as to allow for a load distribution of the critical tensile loads, for example by means of at least one bend (32) in the contact element (31).

The present invention relates first to an additional point of contact for an electric component, particularly for a piezoelectric component of multilayer construction in accordance with the precharacterizing part of patent claim 1. The invention also relates to a piezoelectric component of multilayer construction in accordance with the precharacterizing part of patent claim 8.

Piezoelectric components can be in the form of multilayer components having a number of respectively alternately arranged piezoelectric ceramic layers and electrode layers and are becoming increasingly significant in modern electrotechnology. By way of example, piezoelectric components in the form of piezoelectric actuators are used as servodrives, in connection with valves and the like.

A known piezoelectric actuator is described in DE 196 46 676 C1, for example. In such piezoelectric ceramics, use is made of the effect that these piezoelectric ceramics become charged under mechanical pressure, or tension, and secondly expand along the main axis of the ceramic layer when an electric voltage is applied. To multiply the usable longitudinal expansion, use is made, by way of example, of monolithic multilayer actuators which comprise a sintered stack of thin films made of piezoelectric ceramic (for example lead zirconate titanate) with incorporated metal electrode layers. The electrode layers are reciprocally routed out of the stack and are electrically connected in parallel via external metalized portions. To this end, the two contact sides of the stack have a respective strip-like or band-like, continuous metalized portion on them which is connected to all electrode layers of the same polarity. Between the metalized portion and further electric connection elements of the piezoelectric component there is frequently also an additional point of contact, which can take many forms. If an electric voltage is applied to the electric connection elements, the piezoelectric films expand in the field direction. The mechanical series connection of the individual piezoelectric films means that the nominal expansion of the whole stack is actually reached at relatively low electric voltages.

The mechanical travel means that such actuators are subject to considerable loading. Of crucial significance for the useful life of the actuators in dynamic operation, in order to achieve high cycle numbers and high reliability, is the electric external contact. This can be provided, by way of example, such that a respective additional point of contact, which can be in the form of a Kapton film laminated with copper, for example, is put onto the metalized portions. Such an additional point of contact is also called a contact tab. The total length of this additional point of contact can be connected by means of a suitable connecting means, for example by means of laser soldering or the like, to the respective metalized portion associated therewith. This ensures the electric contact for the piezoelectric component even when there are cracks dividing the metalized portions, for example polarity cracks and the like, in the actuator ceramics. Such cracks do not appear just in the ceramic layers or metalized portions, however.

It is likewise possible for cracks to appear in the additional point of contact during operation of the piezoelectric component. The unavoidable spread of cracks in the additional point of contact, or in the contact tab, during operation of the piezoelectric component is determined by a multiplicity of parameters. The width of the additional point of contact and also the design layout need to be oriented particularly to the preferred directions of crack spread and to the maximum crack lengths which arise.

The earlier patent application DE 197 15 487 A1, likewise submitted by the applicant, describes a piezoelectric actuator in which an actuator stack made of ceramic layers and interposed electrode layers, as described in the introduction, is embedded in a prefabricated hollow profile. To this end, the hollow profile has a central recess at first which corresponds approximately to the shape of the piezoelectric actuator stake. The side walls of this recess are also provided with two slots which lead to further recesses for electric connection elements. This solution provides for the slots to have a curved profile in this case. When the piezoelectric component is now inserted into the hollow profile, the actuator stack is in the central recess, while the electric connection elements are in the recesses which are provided for them. The connection between the electric connection elements and the actuator stack is made via additional points of contact in the form of films. These additional points of contact are situated within the slot, which means that, when fitted, the additional points of contact in the form of flexible films likewise have a slightly curved profile too.

However, such an embodiment of the piezoelectric actuator still cannot stop the spread of cracks growing over the entire area of the additional point of contact completely, which means that, in the worst case, individual actuator regions could become separated from the electric supply line.

On the basis of the stated prior art, the invention is based on the object of developing an additional point of contact and also a piezoelectric component of the type mentioned at the outset further such that it is possible to avoid the drawbacks demonstrated in connection with the prior art. In particular, the aim is to provide a fault-tolerant and, in dynamic operation, low-fatigue additional point of contact for an electrical component, particularly for a piezoelectric component of multilayer construction.

The invention achieves this object by means of the additional point of contact in accordance with patent claim 1 and also by the piezoelectric component of multilayer construction in accordance with patent claim 8. Further advantages, features, details, aspects and effects of the invention can be found in the subclaims, in the description and also in the drawings. Features and details which are described in connection with the inventive additional point of contact naturally also apply in this case to the piezoelectric component, and vice versa.

The first aspect of the invention provides an additional point of contact for an electric component, particularly for a piezoelectric component of multilayer construction, having an electrically conductive contact element for connecting the electric component to at least one electric connection element. In accordance with the invention, the additional point of contact is characterized in that the contact element has a shape which is or can be used to rearrange the stress of the critical tensile loads.

In this case, stress rearrangement is generally understood to mean that at least one portion of the critical tensile loads (for example in the electric component's longitudinal direction) is deflected into other directions in particular regions of the contact element.

This will be explained using a nonexclusive example. By way of example, it is conceivable for the contact element to have a shape where that side of the contact element where said contact element is connected to the electric component is subject to full tensile loading, while stresses in other directions prevail in the contact element in that region in which said contact element is connected to an electric connection element, for example (free region).

The inventive embodiment of the additional point of contact allows fault-tolerant and, in dynamic operation, low-fatigue electric connection of the electric component to at least one electric connection element to be ensured.

To this end, the additional point of contact, and in this case particularly the latter's electrically conductive contact element, now has a quite specific shape. This allows reliable contact for the electric component with simultaneously reduced mechanical stress loading. A basic idea of the invention is therefore a particular layout for the additional point of contact, which is a crucial link element between the electric component and at least one further electric connection element, for example a connector, a contact pin or the like.

The invention now provides for the contact element of the additional point of contact to have a shape such as can be used to reduce critical loads, for example critical tensile/pressure loads, which are alternating loads in the case of a piezoelectric component of multilayer construction, for example an actuator, such that the cracks appearing in the contact element no longer result in the drawback described in the prior art. To this end, the invention provides for the additional point of contact to be in a form such that a stress rearrangement for the critical loads, particularly for the critical tensile loads, now takes place or can take place, which slows down the spread of fatigue cracks and allows it to be stopped within the contact element. It means that the useful life of the electric component provided with the inventive additional point of contact can be increased.

The invention is now limited to particular embodiments of the additional point of contact. A few nonexclusive examples are explained in more detail in the rest of the description.

The form of the contact element can advantageously be chosen such that a voltage reduction is simultaneously achieved in the regions of the contact element, for example the contact tab, which are remote from the electric component.

Advantageously, the contact element can be in the form of an electrically conductive film. Such a film is particularly easy and inexpensive to produce.

Preferably, the contact element can have at least one preshaped portion, particularly a bend. This allows, in particular, the mechanical tensile/pressure loads detrimental to the contact element's fatigue response to be rearranged particularly advantageously, particularly with simultaneous stress reduction in the contact element.

In this case, “preshaped portion” is understood to mean any type of shaping which results in a shape change—particularly one which remains—in the contact element before said contact element is arranged in the electric component.

In contrast thereto, the piezoelectric component described in DE 197 15 487 A1 has an additional point of contact which has merely a curved profile. However, this known additional point of contact, which is produced from a thin film, has no preshaped portion (bend). When the film is inserted into the curved slot, it assumes merely a curved profile. However, the film continues to remain undeformed in this case. When the additional point of contact disclosed in the known solution is removed from the corresponding slots, it will reassume its initial shape on account of its elasticity. This initial shape is a planar area without any deformation.

However, the actual preshaped portion (bend) in the contact element results in the inventive stress rearrangement for the critical tensile loads being able to take place.

Advantageously, the contact element can have at least one bend at an angle of ≦270°. The setting for the most beneficial angle in each case is obtained according to requirements and the instance of application for the electric component and the additional point of contact. In this case, the invention is not limited to particular angles within the stated range. The only important thing is that the selected angles are in defined radii. The contact element can advantageously have at least one bend at an angle of ≦180°.

In another embodiment, the contact element can have a contact region for connection to at least one electric connection element and can have a mounting region for connection to an electric component. Advantageously, the contact element can have at least one preshaped portion, particularly a bend, in the mounting region. This means that rearrangement of the mechanical tensile/pressure loads detrimental to the contact element's fatigue response can simultaneously also involve a reduction in the stress in the regions of the contact element which are remote from the electric component. This allows the spread of fatigue cracks to be slowed down in the contact element and to be stopped in the first half of the contact element. This significantly increases the useful life of the whole electric component, since the cracks in the contact element mean that it is no longer possible for individual regions of the electric component to be separated from the electric supply line, as illustrated as part of the introduction to the description for the previously known solutions.

It is likewise conceivable for the mounting region or else both regions to contain at least one preshaped portion, particularly a bend.

Advantageously, at least regions of the contact element can have a patterned portion. Such a patterned portion on the contact element allows the spread of cracks therein to be slowed down further or stopped. The at least regional patterning of the contact element allows the mechanical stresses in the contact element during operation of the electric component to be minimized.

If the electric component is a piezoelectric component of multilayer construction, for example, then such mechanical stresses are particularly great if a crack, for example as a result of polarization of the piezoelectric component (polarity crack), has arisen in the piezoelectrically inactive region of the component.

Elongation and contraction when there is such a crack involve a relatively large change in the dimensions of the piezoelectric component. This large change gives rise to great mechanical stresses in the contact element, particularly if the contact element is firmly connected to a rigid connection element, for example a contact pin or the like.

The at least regional patterning of the contact element means that it is now possible to achieve an increase in the flexibility of the contact element. This can be done, by way of example, by making at least one cutout and/or at least one thinned portion in the contact element. The shape, size, placement and number of cutouts or thinned portions are advantageously such that the contact element is flexible particularly in the direction of elongation and contraction of the piezoelectric component. One solution to how a contact element can be advantageously patterned is described, by way of example, in the earlier patent application EP 1 065 735 A2, likewise submitted by the applicant, whose disclosed content is incorporated in this regard in the description of the present invention.

Advantageously, at least regions of the additional point of contact can be formed from a metal, particularly a metal from the group Cu, Fe, steel, nickel, cobalt, aluminum, beryllium. With particular advantage, the additional point of contact can be produced from a copper-nickel and/or aluminum base alloy. Of particular advantage is a copper-beryllium and/or nickel-beryllium alloy. These alloys are distinguished by a high fatigue strength and hence by high mechanical long-term stability.

Conceivable materials for the additional points of contact besides metals are nonmetallic conductors such as organic conductor materials and the like.

The second aspect of the invention provides a piezoelectric component of multilayer construction, in which a piezoelectric ceramic layer and an electrode layer are always arranged alternately above one another in order to form a stack and in which at least one first electrode layer and at least one second electrode layer, which comes next in the stack and is adjacent to the first electrode layer, are respectively connected to at least one additional point of contact for the purpose of making electric contact with alternating polarity. In accordance with the invention, the piezoelectric component is characterized in that the additional point of contact is in the inventive form described above.

In this way, it is possible to provide a piezoelectric component having a reliable additional point of contact, where a fault-tolerant and, in dynamic operation, low-fatigue electrical connection of the stack comprising ceramic layers and electrode layers to at least one electric connection element, for example, is ensured.

Advantageously, the at least one first electrode layer and the at least one second electrode layer can be connected to at least one respective metalized portion arranged at the side of the stack in order to make electric contact with alternating polarity, each metalized portion being electrically connected to an additional point of contact. In this case, the connection between the metalized portion and the additional point of contact can be made by means of suitable connecting means, such as a solder connection, a weld connection, or the like. The invention is not limited to particular types of connection between the metalized portion and the additional point of contact.

Preferably, the additional point of contact can have a contact element having a contact region and a mounting region, where the contact element is connected to at least one electric connection element by means of the contact region and where the contact element is connected to the stack (to the electrode layers of the same polarity which are in the stack), particularly to the at least one metalized portion, by means of the mounting region.

Preferably, at least regions of the additional point of contact can be surrounded by a passivation material. A passivation material is a type of protective material and/or insulating material, which can be formed from a plastic, for example. Electric passivation of exposed electric components, such as the contact element of the additional point of contact, the electrode layers which are in a piezoelectric component, and the like, is necessary in order to avoid electrical flashovers and short circuits between adjacent, exposed electric components.

In another embodiment, the stack and the additional point of contact can be arranged in a single casing, preferably made of passivation material. In this case, the contact element of the additional point of contact is preferably sealed close to, that is to say in immediate surroundings of, the stack, using the passivation material, for example a suitable plastic. This means that the contact element is also expanded homogeneously with the stack of the piezoelectric multilayer component in dynamic operation, which significantly reduces mechanical loads on the connecting points between the contact element and the piezoelectric component and also on the contact element itself. This entrainment effect in dynamic operation is ensured, in particular, by the distance between the contact element and the stack being consciously kept as short as possible.

Advantageously, an inventive piezoelectric component as described above can be in the form of a piezoelectric actuator or in the form of a piezoelectric transducer. Exemplary embodiments thereof are stack actuators, transversal actuators, flexural actuators, transducers for medical ultrasound and the like. In particular, the piezoelectric component can be used as a piezoelectric actuator in automobile systems, for example as a drive for petrol and diesel injection systems.

The invention is now explained in more detail using exemplary embodiments with reference to the appended drawing, in which:

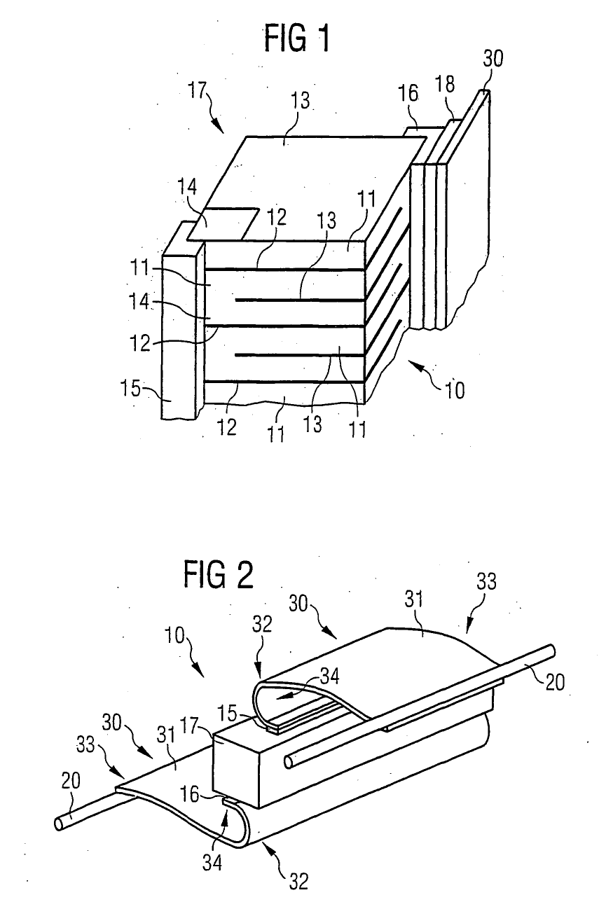

FIG. 1 shows a perspective view of a partial detail from an inventive piezoelectric component of multilayer construction; and

FIG. 2 shows a perspective view of an inventive embodiment of an additional point of contact for an electric component.

FIG. 1 shows a piezoelectric component 10 of multilayer construction which is in the form of a piezoelectric actuator. The piezoelectric actuator 10 forms a stack 17 which is constructed from numerous piezoelectric ceramic layers 11 and electrode layers 12, 13. In this case, the electrode layers 12 and 13 each have a different polarity, with electrode layers of the same polarity being respectively referred to as first electrode layers 12, or second electrode layers 13. The electrode layers 12, or 13, of the same polarity are respectively connected to a common metalized portion 15, or 16.

It is also possible to see inactive insulating zones 14 which are alternately arranged in opposite corners of the successive electrode layers 12, 13, which in this case do not extend over the entire stack cross section.

This design allows the common connection of all first electrode layers 12, or all second electrode layers 13, with the same respective polarity by means of a common, vertical external metalized portion 15, or 16. The external metalized portions 15, 16 can be a corresponding metalized band, for example.

As shown in connection with the metalized portion 16, said metalized portion is connected to an additional point of contact 30 by means of a suitable connecting means 18, which can be a solder connection, a weld connection or the like, for example. In a similar way, the metalized portion 15 can also be connected to an additional point of contact (not shown).

The design and form of the additional point of contact 30 can be seen in FIG. 2.

First of all, FIG. 2 shows the stack 17 of the piezoelectric actuator 10 in greatly simplified form. Two opposite sides of the stack 17 have metalized portions 15, 16, by means of which the stack 17 is connected to electric connection elements 20 using additional points of contact 30. The connection elements 20 are corresponding contact pins, for example.

As can be seen from FIG. 2, the additional point of contact 30 comprises a contact element 31, which can be a film, for example. The contact element 31 has a contact region 33, which makes the connection to the electric connection element 20. The contact element 31 also has a mounting region 34 which connects said contact element to the metalized portion 15, 16.

In order to minimize detrimental mechanical alternating tensile/pressure loads which arise during operation of the piezoelectric actuator 10 and can result in cracks in the contact elements 31, the contact element 31 has at least one preshaped portion, particularly a bend 32.

In the present exemplary embodiment, the at least one bend 32 is formed in the mounting region 34. It is likewise conceivable for the at least one bend 32 to be formed in the contact region 33 or else in both regions. The bend 32 is a preshaped portion of the contact element 31 along a bend line, which is brought about by applying a bending torque, or a bending stress. The bend 32 means that there is a rearrangement of stress for the critical alternating tensile/pressure loads with a simultaneous reduction of stress in regions of the contact element 31 which are remote from the stack 17, in this case in the contact region 33.

This slows down the spread of fatigue cracks in the contact element 31 and even stops it in the first half of the contact element 31, in this case in the mounting region 34. In this way, it is always possible to ensure the electric contact of the stack 17 even when there are cracks in the actuator ceramics which divide the metalized portions 15, 16 and when cracks appear in the additional points of contact 30.

The selection of the angle suitable for the bend 32 is made according to requirements and instance of application. In the exemplary embodiment shown in FIG. 2, a bend angle of 180° has been chosen for the bend 32.

The inventive form of the additional point of contact 30 ensures a fault-tolerant and, in dynamic operation of the piezoelectric actuator 10, low-fatigue electric connection of the stack 17 to the connection elements 20, which is, inter alia, one of the central prerequisites for ensuring that the piezoelectric actuator 10 has a useful life which is sufficiently long for the automobile industry.

1. An additional point of contact for an electric component, particularly for a piezoelectric component of multilayer construction, having an electrically conductive contact element (31) for connecting the electric component (10) to at least one electric connection element (20), characterized in that the contact element (31) has a shape which is or can be used to rearrange the stress of the critical tensile loads.

2. The additional point of contact as claimed in claim 1, characterized in that the contact element (31) is in the form of an electrically conductive film.

3. The additional point of contact as claimed in claim 1 or 2, characterized in that the contact element (31) has at least one preshaped portion, particularly a bend (32).

4. The additional point of contact as claimed in claim 3, characterized in that the contact element has at least one bend (32) at an angle of ≦270°, preferably of ≦180°.

5. The additional point of contact as claimed in one of claims 1 to 4, characterized in that the contact element (31) has a contact region (33) for connection to at least one electric connection element (20) and has a mounting region (34) for connection to an electric component (10) and in that the contact element (31) has at least one preshaped portion, particularly a bend (32), in the mounting region (34).

6. The additional point of contact as claimed in one of claims 1 to 5, characterized in that at least regions of the contact element (31) have a patterned portion.

7. The additional point of contact as claimed in one of claims 1 to 6, characterized in that at least regions thereof are formed from a metal, particularly a metal from the group Cu, Fe, steel, nickel, cobalt, aluminum, beryllium.

8. A piezoelectric component of multilayer construction, in which a piezoelectric ceramic layer (11) and an electrode layer (12, 13) are always arranged alternately above one another in order to form a stack (17) and in which at least one first electrode layer (12) and at least one second electrode layer (13), which comes next in the stack (17) and is adjacent to the first electrode layer, are connected to at least one respective additional point of contact (30) for the purpose of making electric contact with alternating polarity, characterized in that the additional point of contact (30) is in the form as claimed in one of claims 1 to 7.

9. The piezoelectric component as claimed in claim 8, characterized in that the at least one first electrode layer (12) and the at least one second electrode layer (13) are connected to at least one respective metalized portion (15, 16) arranged at the side of the stack (17) in order to make electric contact with alternating polarity, each metalized portion (15, 16) being electrically connected to an additional point of contact (30).

10. The piezoelectric component as claimed in claim 8 or 9, characterized in that the additional point of contact (30) has a contact element (31) having a contact region (33) and a mounting region (34), in that the contact element (31) is connected to at least one electric connection element (20) by means of the contact region (33), and in that the contact element (31) is connected to the stack (17), particularly to the at least one metalized portion (15, 16), by means of the mounting region (34).

11. The piezoelectric component as claimed in one of claims 8 to 10, characterized in that at least regions of the additional point of contact (30) are surrounded by a passivation material.

12. The piezoelectric component as claimed in one of claims 8 to 11, characterized in that the stack (17) and the additional point of contact (30) are arranged in a single casing, preferably made of passivation material.

13. The piezoelectric component as claimed in one of claims 8 to 12, characterized in that it is in the form of a piezoelectric actuator or in the form of a piezoelectric transducer.
